(19) United States
(12) Patent Application Publication
(10) Pub. No.: US 2025/0374600 A1
(43) Pub. Date: Dec. 4, 2025

(54) SEMICONDUCTOR DEVICE AND METHOD OF MANUFACTURING THE SAME

(71) Applicant: Samsung Electronics Co., Ltd., Suwon-si (KR)

(72) Inventors: DONGGON YOO, Suwon-si (KR); SUNJUNG LEE, Suwon-si (KR); RAKHWAN KIM, Suwon-si (KR); DOSUN LEE, Suwon-si (KR)

(21) Appl. No.: 18/931,610

(22) Filed: Oct. 30, 2024

(30) Foreign Application Priority Data
May 30, 2024 (KR) 10-2024-0070503

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121

(57) ABSTRACT

A semiconductor device includes a substrate, an active pattern extending in a first direction on the substrate, a gate electrode extending in a second direction that intersects with the first direction on the substrate, a source/drain pattern on the active pattern, a contact plug spaced apart from the gate electrode in the first direction, an insulating layer on the gate electrode and the contact plug, a first metal layer on the gate electrode in a first hole extending through the insulating layer in a third direction that intersects with the first direction and the second direction, a second metal layer on the contact plug in a second hole extending through the insulating layer in the third direction, a first metal wire on the first metal layer and the insulating layer, and a second metal wire on the second metal layer and the insulating layer.

### CROSS-REFERENCE TO RELATED APPLICATION

This application claims the benefit of Korean Patent Application No. 10-2024-0070503, filed May 30, 2024, in the Korean Intellectual Property Office, the entire disclosure of which is incorporated herein by reference for all purposes.

### BACKGROUND

### 1. Field of the Invention

One or more embodiments relate to a semiconductor device and a method of manufacturing the same.

### 2. Description of the Related Art

In semiconductor devices including semiconductor contacts and wiring structures, when applying an 18-pitch metal gate (gate extension), in a case of a copper damascene method, there are considerations in terms of copper filling margin and resistance. Accordingly, subtractive etching methods are being considered, and a wiring structure that is amenable to etching and has relatively low resistance at a small line width may be desired.

In addition, securing adhesion, increasing resistance due to an adhesive layer, increasing resistance and generating residues due to oxidation during an etching process, and securing alignment between metal wires and metal contacts in the process may be considered.

### SUMMARY

According to an aspect, there is provided a semiconductor device including a substrate, an active pattern extending in a first direction on the substrate, a gate electrode extending in a second direction that intersects with the first direction on the substrate, a source/drain pattern on the active pattern, a contact plug spaced apart from the gate electrode in the first direction, an insulating layer on the gate electrode and the contact plug, a first metal layer on the gate electrode in a first hole extending through the insulating layer in a third direction that intersects with the first direction and the second direction, a second metal layer on the contact plug in a second hole extending through the insulating layer in the third direction, a first metal wire on the first metal layer and the insulating layer, and a second metal wire on the second metal layer and the insulating layer, wherein the gate electrode includes a gate extension portion that intersects with the active pattern, and a gate contact protruding from the gate extension portion in the third direction and formed in the first hole, and wherein the contact plug includes a source/drain contact area on the source/drain pattern, and an upper contact area protruding from the source/drain contact area in the third direction and formed in the second hole.

According to another aspect, there is provided a method of manufacturing a semiconductor device, the method including preparing a substrate including a contact plug, a gate electrode, and an interlayer insulating layer, forming a first insulating film on the contact plug, the gate electrode, and the interlayer insulating layer, and forming a second insulating film on the first insulating film, forming a metal layer in a hole in which the contact plug and the gate electrode are at least partially exposed, removing the first insulating film, the second insulating film, a portion of the contact plug, a portion of the gate electrode, and a portion of the interlayer insulating layer, of an area other than an area where the metal layer is formed, forming an insulating layer on the area, from which the first insulating film, the second insulating film, the portion of the contact plug, the portion of the gate electrode, and the portion of the interlayer insulating layer are removed, and the metal layer, forming a third insulating film on the insulating layer, at least partially exposing the metal layer by removing the third insulating film and a portion of the insulating layer, and forming a metal wire on a surface including the exposed metal layer, wherein, in the forming of the first insulating film and the second insulating film, the first insulating film and the second insulating film have a hole in which each of the contact plug and the gate electrode is exposed.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1A is a plan view illustrating a first direction (an X direction) of a semiconductor device according to an embodiment;

FIG. 1B illustrates a first direction (X direction) conceptual cross-sectional view passing through a gate electrode of a semiconductor device according to an embodiment;

FIG. 1C illustrates a first direction (X direction) conceptual cross-sectional view passing through a contact plug of a semiconductor device according to an embodiment;

FIG. 2A illustrates a conceptual cross-sectional view of another embodiment of a box A indicated by a dashed line in FIG. 1B;

FIG. 2B illustrates a conceptual plan view of another embodiment of a portion along a first direction cutting line B indicated by a dashed line in FIG. 1B;

FIG. 2C illustrates a conceptual cross-sectional view of still another embodiment of a box A indicated by a dashed line in FIG. 1B;

FIG. 2D illustrates a conceptual cross-sectional view of still another embodiment of a portion along a first direction cutting line B indicated by a dashed line in FIG. 1B;

FIG. 3A is a plan view illustrating a second direction (a Y direction) of a semiconductor device according to an embodiment;

FIG. 3B illustrates a second direction (Y direction) conceptual cross-sectional view passing through a gate electrode of a semiconductor device according to an embodiment;

FIG. 3C illustrates a second direction (Y direction) conceptual cross-sectional view passing through a contact plug of a semiconductor device according to an embodiment;

FIG. 4 illustrates a conceptual enlarged view of a connection portion (a box C indicated by a dotted line in FIG. 3B) between a metal layer and a metal wire on a gate contact of a semiconductor device according to an embodiment;

FIG. 5 illustrates a conceptual enlarged view of a connection portion (a box D indicated by a dotted line in FIG. 3C) between a metal layer and a metal wire on an upper contact area of a semiconductor device according to an embodiment;

FIG. 6 illustrates a conceptual view of an operation of preparing a substrate including a contact plug, a gate electrode, and an interlayer insulating layer according to an embodiment;

FIG. 7 illustrates a conceptual view of an operation of forming a first insulating film on a contact plug, a gate electrode, and an interlayer insulating layer, and forming a second insulating film on the first insulating film according to an embodiment;

FIG. 8 illustrates a conceptual view of an operation of forming a metal layer in a hole where a contact plug and a gate electrode are at least partially exposed, according to an embodiment;

FIG. 9 illustrates a conceptual view of an operation of removing a first insulating film, a second insulating film, a portion of a contact plug, a portion of a gate electrode, and a portion of an interlayer insulating layer, of an area other than an area where a metal layer is formed, according to an embodiment;

FIG. 10 illustrates a conceptual view of an operation of forming an insulating layer on an area, from which a first insulating film, a second insulating film, a portion of a contact plug, a portion of a gate electrode, and a portion of an interlayer insulating layer are removed, and a metal layer, and forming a third insulating layer on the insulating layer, according to an embodiment;

FIG. 11 illustrates a conceptual view of an operation of exposing a metal layer by removing a third insulating film and a portion of an insulating layer according to an embodiment; and

FIGS. 12 and 13 illustrate conceptual views of an operation of forming a metal wire on a surface including an exposed metal layer according to an embodiment.

### DETAILED DESCRIPTION

Hereinafter, embodiments will be described in detail with reference to the accompanying drawings. However, various alterations and modifications may be made to the embodiments and thus, the scope of the disclosure is not limited or restricted to the embodiments. The equivalents should be understood to include all changes, equivalents, and replacements within the idea and the technical scope of the disclosure.

The terminology used herein is for the purpose of describing particular embodiments only and is not to be limiting of the embodiments. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. As used herein, the term “and/or” includes any and all combinations of one or more of the associated listed items. In the description of embodiments, detailed description of well-known related structures or functions will be omitted when it is deemed that such description will cause ambiguous interpretation of the present disclosure. In addition, the terms first, second, A, B, (a), and (b) may be used to describe constituent elements of the embodiments. These terms are used only for the purpose of discriminating one component from another component, and the nature, the sequences, or the orders of the components are not limited by the terms. It should be noted that if it is described that one component is “connected”, “coupled”, or “joined” to another component, a third component may be “connected”, “coupled”, and “joined” between the first and second components, although the first component may be directly connected, coupled, or joined to the second component.

A component, which has the same common function as a component included in any one embodiment, will be described by using the same name in other embodiments. Unless disclosed to the contrary, the description of any one embodiment may be applied to other embodiments, and the specific description of the repeated configuration will be omitted. That is, all embodiments and/or features of any embodiments can be combined in any way and/or combination.

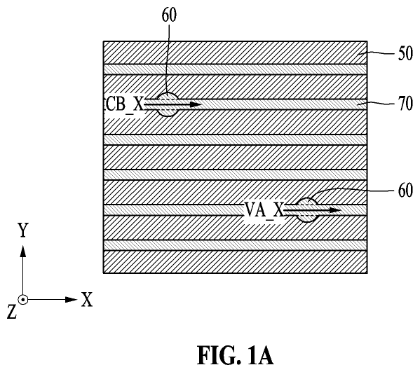

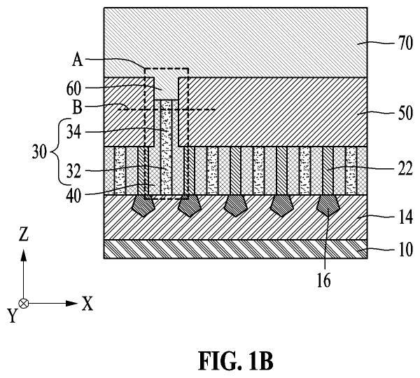

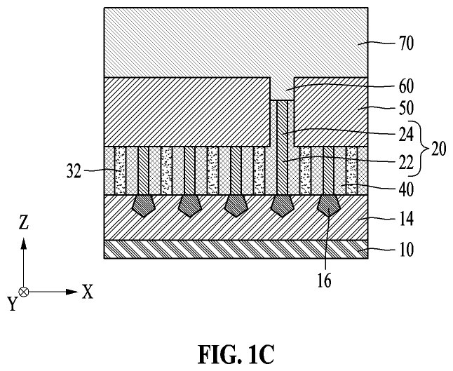

FIG. 1A is a plan view illustrating a first direction (an X direction) of a semiconductor device according to an embodiment, and FIG. 1B illustrates a first direction (X direction) conceptual cross-sectional view passing through a gate electrode 30 of a semiconductor device according to an embodiment, and FIG. 1C illustrates a first direction (X direction) conceptual cross-sectional view passing through a contact plug 20 of a semiconductor device according to an embodiment.

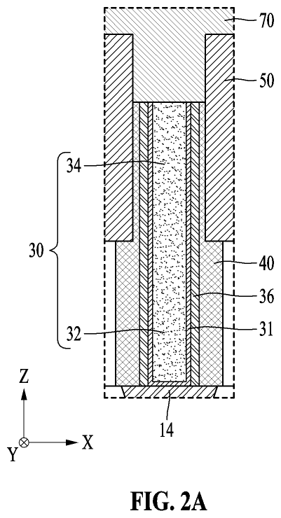

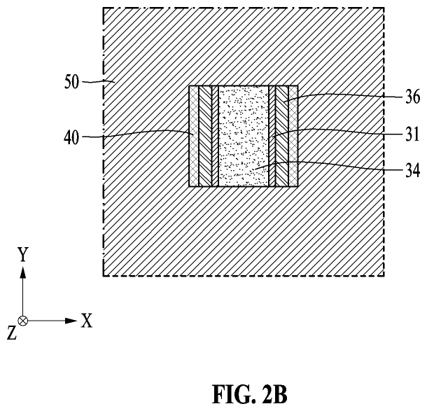

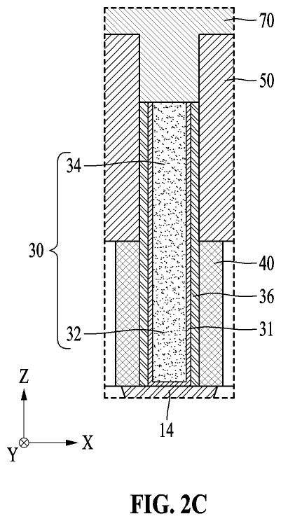

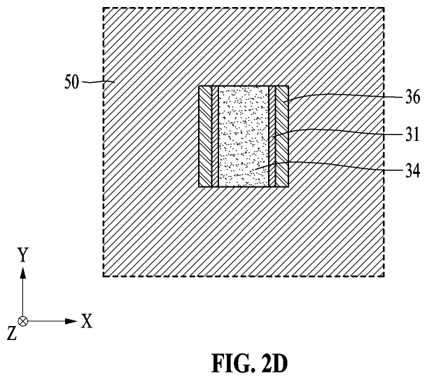

FIG. 2A illustrates a conceptual cross-sectional view of another embodiment of a box A indicated by a dashed line in FIG. 1B, FIG. 2B illustrates a conceptual plan view of another embodiment of a portion along a first direction cutting line B indicated by a dashed line in FIG. 1B, FIG. 2C illustrates a conceptual cross-sectional view of still another embodiment of a box A indicated by a dashed line in FIG. 1B, and FIG. 2D illustrates a conceptual cross-sectional view of still another embodiment of a portion along a first direction cutting line B indicated by a dashed line in FIG. 1B.

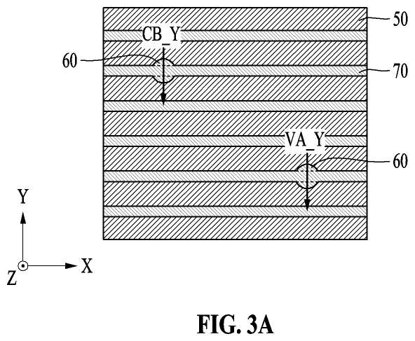

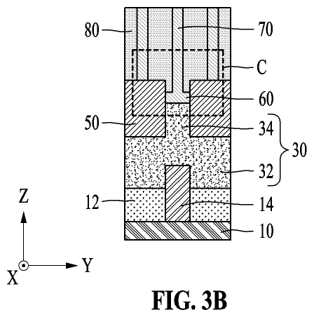

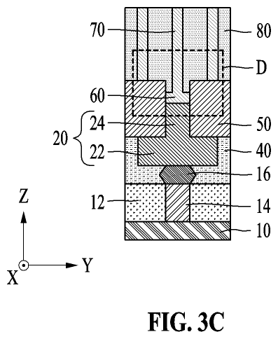

FIG. 3A is a plan view illustrating a second direction (a Y direction) of a semiconductor device according to an embodiment, FIG. 3B illustrates a second direction (Y direction) conceptual cross-sectional view passing through the gate electrode 30 of a semiconductor device according to an embodiment, and FIG. 3C illustrates a second direction (Y direction) conceptual cross-sectional view passing through the contact plug 20 of a semiconductor device according to an embodiment.

The first direction (X direction) may be a direction parallel to an upper surface of a substrate 10. The second direction (Y direction) may be a direction parallel to the upper surface of the substrate 10 and perpendicular to the first direction (X direction).

A semiconductor device according to an embodiment of the present disclosure includes the substrate 10, an active pattern 14 extending in the first direction on the substrate 10, the gate electrode 30 extending in the second direction that intersects with the first direction on the substrate 10, a source/drain pattern 16 formed on the active pattern 14, the contact plug 20 spaced apart from the gate electrode 30 in the first direction, an insulating layer 50 formed on the gate electrode 30 and the contact plug 20, a first metal layer 60 formed on the gate electrode 30 in a first hole penetrating or extending through the insulating layer 50 in a third direction (a Z direction) that intersects with the first direction and the second direction, a second metal layer 60 formed on the contact plug 20 in a second hole penetrating or extending through the insulating layer 50 in the third direction, a first metal wire 70 formed on the metal layer 60 and the insulating layer 50.

The contact plug 20 may include a source/drain contact area CA 22 and an upper contact area VA 24, and the gate electrode 30 may include a gate extension portion MG 32 that intersects with the active pattern 14, and a gate contact CB 34 protruding from the gate extension portion MG 32 in the third direction (Z direction) and formed in the first hole.

The gate electrode 30 may include the gate extension portion MG 32 formed at a lower position than a lower surface of the insulating layer 50, and the gate contact CB 34 that protrudes on the gate extension portion MG 32 in the third direction (Z direction) and overlaps the insulating layer 50 in the first direction (X direction) and the second direction (Y direction). The third direction (Z direction) may be a direction that intersects with the first direction (X direction) and the second direction (Y direction).

The contact plug 20 may include the source/drain contact area CA 22 formed at a lower position than a lower surface of the insulating layer 50, and the upper contact area VA 24 that protrudes on the source/drain contact area CA 22 in the third direction (Z direction) and overlaps the insulating layer 50 in the first direction (X direction) and the second direction (Y direction).

The source/drain contact area CA 22 of the semiconductor device according to an embodiment of the present disclosure may be a trench type, the upper contact area VA 24 may be a hole type, the gate extension portion MG 32 may be a trench type, and the gate contact CB 34 may be a hole type. However, embodiments of the present disclosure are not limited thereto.

FIGS. 1A and 2A illustrate the gate contact CB 34 and the upper contact area VA 24 one by one in the first direction (X direction) and the second direction (Y direction) without overlapping each other, however this is merely an example. In another example, the gate contact CB 34 and the upper contact area VA 24 may overlap each other in the first direction (X direction) or the second direction (Y direction), and the semiconductor device may have a plurality of them. The metal layer 60 formed on the gate contact CB 34 and the metal layer 60 formed on the upper contact area VA 24 may also overlap each other in the first direction (X direction) or the second direction (Y direction).

First, referring to FIG. 1A, as an example, the metal wire 70 may extend in the first direction (X direction). The first direction (X direction) may be a direction parallel to the upper surface of the substrate 10. It is seen that the metal layer 60 connected to the upper contact area VA 24 is positioned on one of the metal wires M1 70, and the metal layer 60 connected to the gate contact CB 34 is positioned on the other one of the metal wires M1 70. In an example, the metal layer 60 may be disposed in a hole formed in the insulating layer 50, and a planar shape thereof may be circle. However, the planar shape of the metal layer 60 is not limited to a circle, and when the metal layer 60 has a cylindrical shape, for example, it may be referred to as a pillar. In the second direction (Y direction) that intersects with the direction in which the metal wire 70 extends, a width of the metal layer 60 may be greater than a width of the metal wire 70.

As shown in FIG. 1B, the metal wire M1 70 may be connected to the gate extension portion MG 32 by passing the gate contact CB 34 through the hole-type metal layer 60 formed in the hole in the insulating layer 50. As shown in the first direction (X direction) conceptual cross-sectional view (FIG. 1B) passing through the gate electrode 30 (the gate extension portion MG 32 and the gate contact CB 34), the interlayer insulating layer 40 that electrically disconnects the gate extension portion MG 32 and the source/drain contact area CA 22 may also extend between the gate contact CB 34 and the insulating layer 50.

The interlayer insulating layer 40 may include any one material selected from a group consisting of silicon oxide (SiO₂), silicon nitride (SiN), silicon oxynitride (SiON), and silicon oxycarbide (SiOCN).

Meanwhile, as shown in FIG. 1B, the width of the metal layer 60 in the first direction (X direction) may be greater than the width of the gate contact CB 34.

As shown in FIG. 1C, the metal wire M1 70 may be connected to the source/drain contact area CA 22 by passing through the upper contact area VA 24 through the hole-type metal layer 60 formed in the hole in the insulating layer 50. As shown in the X direction conceptual cross-sectional view (FIG. 1C) passing through the contact plug 20 (the source/drain contact area CA 22 and the upper contact area VA 24), the interlayer insulating layer 40 that electrically disconnects the gate extension portion MG 32 and the source/drain contact area CA 22 may also extend between the upper contact area VA 24 and the insulating layer 50.

Meanwhile, as shown in FIG. 1C, the width of the metal layer 60 in the first direction (X direction) may be greater than the width of the upper contact area VA 24.

As shown in FIGS. 2A and 2B, a gate spacer 36 may be formed on a side surface of the gate electrode 30 (the gate extension portion MG 32 and the gate contact CB 34) in the first direction (X direction), and a gate insulating layer 31 may be formed between the gate electrode 30 (the gate extension portion MG 32 and the gate contact CB 34) and the gate spacer 36, and between the gate extension portion MG 32 and the active pattern 14. The gate insulating layer 31 may contain a highly dielectric material (high-k material), such as silicon oxide, silicon nitride, aluminum oxide, hafnium oxide, zirconium oxide, metal nitride oxide, silicate, aluminate, etc., or may also contain a two-dimensional (2D) insulator, such as h-BN (hexagonal boron).

Depending on the method of forming a hole in the insulating layer 50, as shown in FIGS. 2A and 2B, the gate insulating layer 31, the gate spacer 36, and the interlayer insulating layer 40 may be formed between the gate contact CB 34 and the insulating layer 50, and as shown in FIGS. 2C and 2D, only the gate insulating layer 31 and the gate spacer 36 may be formed between the gate contact CB 34 and the insulating layer 50 without the interlayer insulating layer 40 so that the gate spacer 36 may contact the insulating layer 50.

As shown in FIGS. 2A and 2B, the semiconductor device may include the gate spacer 36 formed on the side surface of the gate electrode 30 in the first direction (X direction), and the interlayer insulating layer 40 extending between the gate spacer 36 and the insulating layer 50. The interlayer insulating layer 40 may be formed to extend between the gate contact CB 34 and the insulating layer 50 and between the upper contact area VA 24 and the insulating layer 50. An area of the gate spacer 36 that overlaps the gate contact CB 34 in the first direction (X direction) may contact the insulating layer 50 in the second direction (Y direction). An area of the gate insulating layer 31 that overlaps the gate contact CB 34 in the first direction (X) may contact the insulating layer 50 in the second direction (Y direction). In addition, the area of the interlayer insulating layer 40 that overlaps the gate contact CB 34 in the first direction (X direction) may contact the insulating layer 50 in the first direction (X direction) and the second direction (Y direction).

In another example, as shown in FIGS. 2C and 2D, the area of the gate spacer 36 that overlaps the gate contact CB 34 in the first direction (X direction) may contact the insulating layer 50 in the first direction (X direction) and the second direction (Y direction). The gate spacer 36 and the insulating layer 50 may directly contact each other without the interlayer insulating layer 40 between the gate spacer 36 and the insulating layer 50.

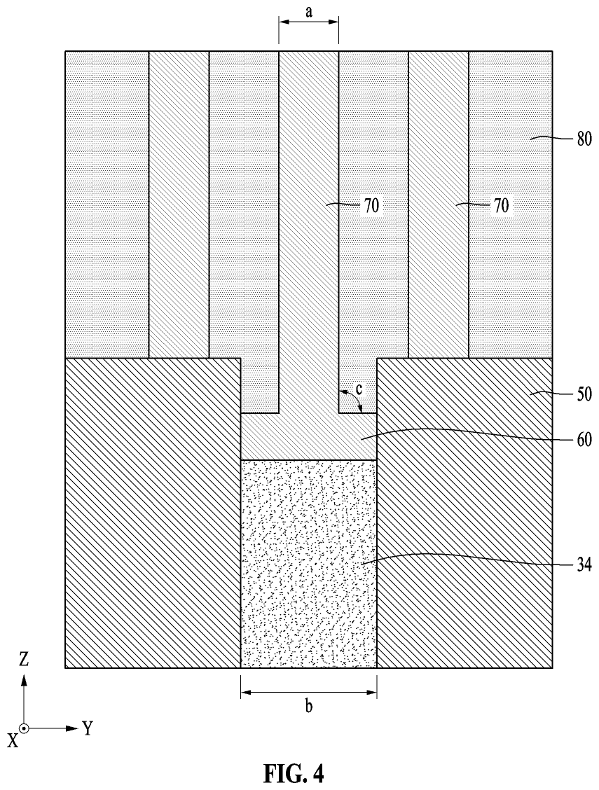

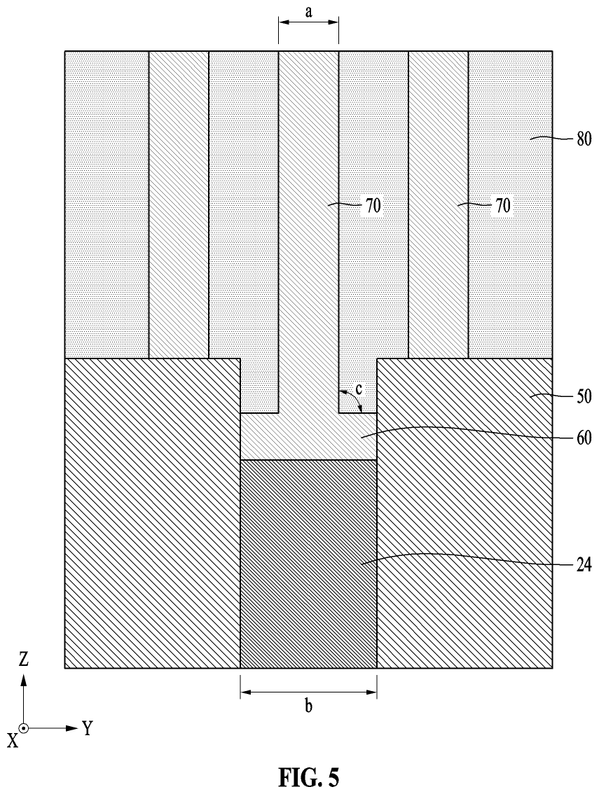

In FIGS. 3B and 3C, the relative sizes (widths or diameters) of the gate contact CB 34, the metal layer 60, and metal wire M1 70 may be obtained. This will be described in more detail in the description of FIGS. 4 and 5 below.

As shown in FIGS. 3B and 3C, a space between the metal wires 70 may be filled with an insulating material 80. The insulating material 80 may include any one material selected from a group consisting of silicon oxide (SiO₂), silicon nitride (SiN), silicon oxynitride (SiON), and silicon oxycarbide (SiOCN).

In an embodiment, through the metal layer 60, the metal wire M1 70 and the gate contact CB 34 may be connected to each other, and the metal wire 70 and the upper contact area VA 24 may be connected to each other without TiN.

In FIGS. 3B and 3C, upper surfaces of the source/drain contact area CA 22 and the gate extension portion MG 32 may be at substantially the same level (height) (substantially the same level in the third direction (Z direction)), and upper surfaces of the upper contact area VA 24 and the gate contact CB 34 may be at substantially the same level (height) (substantially the same level in the third direction (Z direction)).

In FIG. 3B, the active pattern 14 is aligned with the gate contact CB 34 in the third direction (Z direction), however, in another example, the active pattern 14 and the gate contact CB 34 may not be aligned in the third direction (Z direction). In addition, although only one active pattern 14 is shown in FIG. 3B, in another example, a plurality of active patterns spaced apart in the second direction (Y direction) and extending in the first direction (X direction) may be formed between the gate electrode 30 and the substrate 10. In FIG. 3B, the gate insulating layer 31 may be formed between the gate electrode 30 and the active pattern, and between the gate electrode 30 and a field insulating layer 12.

In FIG. 3C, although the active pattern 14 is aligned with the upper contact area VA 24 in the third direction (Z direction), in another example, the active pattern 14 and the upper contact area CB 34 may not be aligned in the third direction (Z direction). In addition, although only one active pattern 14 is shown in FIG. 3C, a plurality of active patterns spaced apart in the second direction (Y direction) and extending in the first direction (X direction) may be formed between the contact plug 20 and the substrate 10. The source/drain pattern 16 may be formed on each of the plurality of active patterns, and the source/drain contact area CA 22 of the contact plug 20 may be electrically connected to the plurality of source/drain patterns 16. The plurality of source/drain patterns 16 adjacent in the second direction (Y direction) may be directly connected to each other.

FIG. 4 is an enlarged view of an area C of FIG. 3B, and FIG. 5 is an enlarged view of an area D of FIG. 3C.

As shown in FIGS. 4 and 5, the metal layer 60 on the gate contact CB 34 and the upper contact area VA 24 may have a greater width in the second direction (Y direction) than the metal wire 70. When the metal layer 60 has a hole-type shape, a diameter b of the metal layer 60 may be greater than a width a of the metal wire M1 70 formed on the metal layer 60.

As in the present disclosure, when the width of the metal layer 60 is greater than the width of the metal wire M1 70 formed on the metal layer 60, an alignment margin is secured in the manufacturing process, thereby improving ease of production.

According to another embodiment of the present disclosure, an angle c between the upper surface of the first metal layer 60 and the side surface of the first metal wire M1 70 may be about 90° to 100°.

According to another embodiment of the present disclosure, the first metal layer 60 and the first metal wire 70 may be formed of the same material and may be integrally formed, e.g., formed as a monolithic structure, and the second metal layer 60 and the second metal wire 70 may be formed of the same material and may be integrally formed, e.g., formed as a monolithic structure.

In an example, the metal layer 60 may be formed and the metal wire 70 may be formed separately on the metal layer 60. In an example, the metal layer 60 and the metal wire 70 may be formed with a level difference by one etching after deposition. In this case, an interface between the metal layer 60 and the metal wire 70 does not appear, thereby reducing or preventing the generation of resistance at the interface. That is, there may or may not be an interface at the boundary between the metal layer 60 and the metal wire 70. When there is a level difference even when there is no interface at the boundary between the metal layer 60 and the metal wire 70, that is, the metal layer 60 having a width (a diameter in a case of a circular shape) greater than a width of the metal wire 70 has a corresponding structure, it falls within the scope of the claims of the present disclosure, and it should not be interpreted as not falling within the scope of the present disclosure because the metal layer 60 and the metal wire 70 are not distinguished.

The upper surface of the (first) metal layer 60 formed on the gate contact CB 34 may have substantially the same level in the third direction (Z direction) with the upper surface of the (second) metal layer 60 formed on the upper contact area VA 24. The upper surface of the (first and second) metal layer 60 may be an interface between the metal layer 60 and the insulating material 80. In other embodiments, the upper surface of the (first and second) metal layer 60 may be an interface between the (first and second) metal layer 60 and the metal wire 70. The upper surface of the (first and second) metal layer 60 may be formed at a lower level than the upper surface of the insulating layer 50 in the third direction (Z direction).

The lower surface of the (first and second) metal layer 60 formed on the gate contact CB 34 may have substantially the same level as the lower surface of the (first and second) metal layer 60 formed on the upper contact area VA 24 in the third direction (Z direction). The lower surface of the metal layer 60 may be an interface between the metal layer 60 and the interlayer insulating layer 40. The lower surface of the metal layer 60 may be an interface between the metal layer 60 and the gate contact CB 34. The lower surface of the metal layer 60 may be an interface between the metal layer 60 and the upper contact area VA 24.

According to an embodiment, the insulating layer 50 may contain SiN, SiO₂, or a combination thereof.

The drawings of the present disclosure illustrate an example where the interlayer insulating layer 40 contains SiO₂ and the insulating layer 50 contains SiN, however embodiments of the present disclosure are not limited thereto, and may contain any or all of examples in which the interlayer insulating layer 40 and the insulating layer 50 both contain SiO₂, an example in which the interlayer insulating layer 40 and the insulating layer 50 both contain SiN, an example in which the interlayer insulating layer 40 contains SiN and the insulating layer 50 contains SiO₂, and an example in which the interlayer insulating layer 40 and the insulating layer 50 contain a combination thereof. In an example, the material of the interlayer insulating layer 40 or the insulating layer 50 may vary depending on what metal the metal wire 70 contains. For example, because a bonding force between Ru and SiN is stronger than a bonding force between Ru and SiO₂, when the metal wire 70 is formed of Ru, a SiN insulating layer may be used as the insulating layer 50 that directly contacts the metal wire 70, to inhibit or prevent Ru from peeling off during the process. As described above, when the metal wire 70 is formed of Ru, if the insulating layer 50 is formed of SiN, a TiN adhesive layer for increasing adhesive strength may not be used, thereby mitigating or preventing an increase in resistance, generation of TiN residues during an etching process, process complexity, and cost increase, which are caused by the use of the TiN adhesive layer.

According to another embodiment of the present disclosure, the source/drain contact area CA 22, the upper contact area VA 24, the first metal layer 60, the second metal layer, the first metal wire 70, and the second metal wire 70 may each include at least one material selected from a group consisting of Ru, W, Mo, Ni, Al, and Co.

According to another embodiment of the present disclosure, the gate extension portion MG 32 and the gate contact CB 34 may each include at least one material selected from a group consisting of TiN, TiAlC, TaN, and TaAlC.

According to another embodiment of the present disclosure, the source/drain contact area CA 22 and the upper contact area VA 24 may contain the same component, the gate extension portion MG 32 and the gate contact CB 34 may contain the same component, and the metal layer 60 and the metal wire 70 may contain the same component.

That is, the source/drain contact area CA 22 and the upper contact area VA 24 may contain Mo in the same manner, and the gate extension portion MG 32 and the gate contact CB 34 may contain TiN in the same manner, and the metal layer 60 and the metal wire 70 may contain Ru in the same manner.

The gate electrode 30 may include a conductive material, and may include at least one of a metal nitride, such as titanium nitride (TiN), tantalum nitride (TaN), or tungsten nitride (WN), a metal material, such as aluminum (Al), tungsten (W), or molybdenum, or a semiconductor material, such as doped polysilicon. The gate electrodes 30 may be composed of two or more multilayers. The gate electrode 30 may extend lengthwise in the second direction (Y direction). The gate electrode 30 may be disposed between field insulating layer 12 and insulating layer 50.

The gate electrode 30 may have a structure in which a portion of an upper region is recessed to form a level difference. More specifically, the gate electrode 30 may include the gate extension portion MG 32 formed on the field insulating layer 12 and the active pattern 14, and the gate contact CB 34 formed on the gate extension portion MG 32.

A lower surface of the gate extension portion MG 32 may contact the field insulating layer 12, and an upper surface of the gate extension portion MG 32 may contact the insulating layer 50. The gate extension portion MG 32 may extend lengthwise in the second direction (Y direction) while at least partially surrounding an upper portion of the active pattern 14. The upper surface of the gate extension portion MG 32 may have substantially the same level as the upper surface of the source/drain contact area CA 22 of the contact plug 20. (Z direction) For example, a distance from the upper surface of the substrate 10 to the upper surface of the gate extension portion MG 32 may be substantially the same as a distance from the upper surface of the substrate 10 to the upper surface of the source/drain contact area CA 22.

The gate contact CB 34 may have a shape that protrudes from the gate extension portion MG 32 in the third direction (Z direction). In the second direction (Y direction), the gate contact CB 34 may be formed inside the hole of the insulating layer 50. In the second direction (Y direction), both side surfaces of the gate contact CB 34 may contact the insulating layer 50. In the first direction (X direction), the gate contact CB 34 may be formed between the insulating layers 50. In the first direction (X direction), the gate contact CB 34 may be formed between the interlayer insulating layers 40. In the first direction (X direction), both side surfaces of the gate contact CB 34 may contact the interlayer insulating layer 40. The upper surface of the gate contact CB 34 may contact the lower surface of the metal layer 60. In the second direction (Y direction), the gate extension portion MG 32 may have a length greater than that of the gate contact CB 34. In addition, in the first direction (X direction), the gate extension portion MG 32 and the gate contact CB 34 may have substantially the same length.

The source/drain patterns 16 may be provided on the upper portions of the active patterns. The source/drain patterns 16 may be an epitaxial pattern formed by a selective epitaxial growth process. The source/drain patterns 16 may include p-type or n-type conductive impurities. A channel pattern may be interposed between the source/drain patterns 16. The channel pattern may be an area between the source/drain patterns 16 in the upper portion of the active pattern 14. If the semiconductor device includes a gate all around-type metal oxide semiconductor field effect transistor (MOSFET), the channel pattern may include a plurality of nanosheets spaced apart from the active pattern 14 in the third direction (Z direction). In this case, the gate electrode 30 may be formed to at least partially surround each of the plurality of nanosheets. The upper surface of the source/drain patterns 16 may be coplanar with the upper surface of the channel pattern or may be higher than the upper surfaces of the channel pattern (Z direction).

The source/drain patterns 16 may include a semiconductor element (e.g., silicon germanium) having a lattice constant greater than a lattice constant of the semiconductor element of the substrate 10. Thus, the source/drain patterns 16 may provide compressive stress to the channel pattern. In an example, the source/drain patterns 16 may include the same semiconductor element (e.g., silicon) as the substrate 10.

The contact plug 20 may have a structure in which a portion of the upper region is recessed to form a level difference. More specifically, the contact plug 20 may include the source/drain contact area CA 22 and a upper contact area VA 24.

The lower surface of the contact plug 20 may contact the field insulating layer 12, and the upper surface of the source/drain contact area CA 22 may contact the insulating layer 50. The lower surface of the source/drain contact area CA 22 may contact the upper surface of the source/drain pattern 16 formed on the active pattern 14. The upper surface of the source/drain contact area CA 22 may have substantially the same level as the upper surface of the gate extension portion MG 32 of the gate electrode 30 (Z direction). For example, the distance from the upper surface of the substrate 10 to the upper surface of the source/drain contact area CA 22 may be substantially the same as the distance from the upper surface of the substrate 10 to the upper surface of the gate extension portion MG 32.

The upper contact area VA 24 may have a shape that protrudes from the source/drain contact area CA 22 in the third direction (Z direction). In the second direction (Y direction), the upper contact area VA 24 may be formed inside the hole of the insulating layer 50. In the second direction (Y direction), both side surfaces of the upper contact area VA 24 may contact the insulating layer 50. In the first direction (X direction), the upper contact area VA 24 may be formed between the insulating layers 50. In the first direction (X direction), the upper contact area VA 24 may be formed between the interlayer insulating layers 40. In the first direction (X direction), both side surfaces of the upper contact area VA 24 may contact the interlayer insulating layer 40. The upper surface of the upper contact area VA 24 may contact the lower surface of the metal layer 60. In the second direction (Y direction), the source/drain contact area CA 22 may have a length greater than the upper contact area VA 24. In addition, in the first direction (X direction), the source/drain contact area CA 22 and the upper contact area VA 24 may have substantially the same length.

The insulating layer 50 may include at least one material selected from a group consisting of silicon oxide (SiO₂), silicon nitride (SiN), silicon oxynitride (SiON), and silicon oxycarbide (SiOCN).

The insulating layer 50 may be formed between the metal wire 70, the contact plug 20, and the gate electrode 30. Among the gate electrodes 30, the gate contact CB 34 may be connected to the metal layer 60 through a hole of the insulating layer 50. In the hole of the insulating layer 50, the gate insulating layer 31 and the gate spacer 36 may be included between the insulating layer 50 and the gate contact CB 34. The interlayer insulating layer 40 may be included between the gate spacer 36 and the insulating layer 50.

The active pattern 14 may be formed on the substrate 10, and upper portions of the substrate 10 protruding in the third direction may be defined as the active patterns 14. The active patterns 14 may be spaced apart from each other. The active patterns 14 may be defined by a device isolation film (STI) in the space provided between the active patterns 14. Each active pattern 14 may be at least partially surrounded by the device isolation film (STI). The device isolation film (STI) may be the field insulating layer 12. The upper surface of the active pattern 14 may be formed to be higher than the upper surface of the field insulating layer 12 (Z direction), and may be at least partially surrounded by the gate extension portion MG 32 in the gate electrode 30. The source/drain pattern 16 may be formed on the active pattern 14, the source/drain contact area CA 22 in the contact plug 20 may be formed on the source/drain pattern 16, and the plurality of source/drain patterns 16 may be provided on the active pattern 14. The source/drain patterns 16 may be areas of n-type or p-type impurities. A channel pattern may be interposed between a pair of source/drain patterns 16. In other words, the channel pattern may connect a pair of source/drain patterns 16 to each other.

According to another embodiment of the present disclosure, the gate contact CB 34 may be (TiN) adhesive layer-free that directly contacts with the first metal layer 60, the upper contact area VA 24 may be (TiN) adhesive layer-free that directly contacts the second metal layer 60, and the first metal wire 70 and the second metal wire 70 may be (TiN) adhesive layer-free that directly contacts the insulating layer 50.

A separate TiN adhesive layer may be used to increase the adhesive strength between the metal wire 70 and the insulating layer 50, and the adhesive strength between the metal layer 60 and the gate contact CB 34 and upper contact area VA 24, however, it may cause an increase in resistance, generation of TiN residues in the etching process, process complexity, and cost increase. To improve the adhesive strength between the metal wire 70 and the insulating layer 50, an insulating layer material with high adhesive strength to a metal wire material may be used (the present disclosure is not limited thereto, but for example, SiN may be used as an insulating layer material in a case of a Ru metal wire). To increase the adhesive strength between the metal wire 70 and the gate contact CB 34 and the upper contact area VA 24, the metal layer 60 may be formed between the metal wire 70 and the gate contact CB 34 and between the metal wire 70 and the upper contact area VA 24. Through this, a (TiN) adhesive layer-free structure that does not use a separate TiN adhesive layer may be provided.

In embodiments of the present disclosure, an insulating film and an insulating layer are not terms that have a particular technical difference, and in their technical meaning, an insulating film may also be interpreted as an insulating layer, and an insulating layer may also be interpreted as an insulating film.

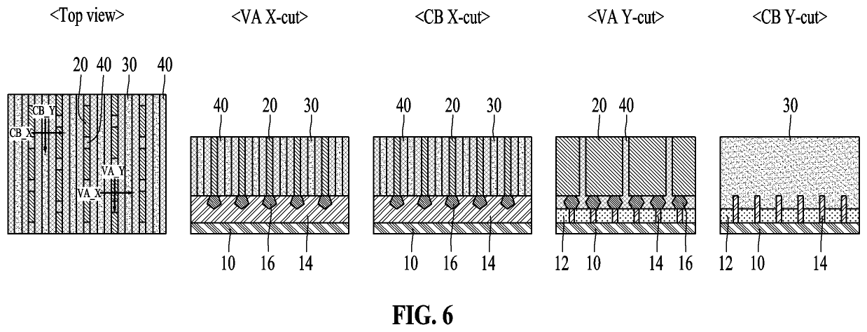

A method of manufacturing the semiconductor device of the present disclosure will be described with reference to FIGS. 6 to 13.

A device area on the substrate 10 may have various components, such as the field insulating layer 12, the active pattern 14, the source/drain pattern 16, and the interlayer insulating layer 40, and the gate insulating layer 31 and the gate spacer 36 may be formed on both side surfaces of the gate electrode 30 (the gate extension portion MG 32 and the gate contact CB 34) in the first direction (X direction), however, FIGS. 6 to 13 illustrate the components in a simplified manner in consideration of the complexity of the drawings. However, it does not exclude that the semiconductor device of embodiments of the present disclosure includes the corresponding components in various forms.

As shown in FIG. 6, the contact plug 20, the gate electrode 30, and the interlayer insulating layer 40 between the contact plug 20 and the gate electrode 30 may be formed on the substrate 10. The substrate 10 may be a semiconductor substrate or a compound semiconductor substrate containing silicon, germanium, or silicon-germanium, and the substrate 10 may be, for example, a silicon substrate. The field insulating layer 12, the active pattern 14, the source/drain pattern 16, and the interlayer insulating layer 40 may be formed on the substrate 10.

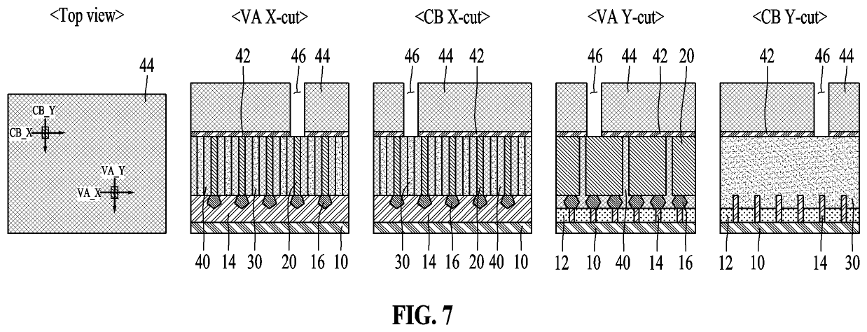

As shown in FIG. 7, according to an embodiment, the first insulating film 42 may be formed on the contact plug 20, the gate electrode 30, and the interlayer insulating layer 40, and the second insulating film 44 may be formed on the first insulating film 42. Holes 46 through which the contact plug 20 and the gate electrode 30 are at least partially exposed are formed in the first insulating film 42 and the second insulating film 44, respectively. According to another embodiment of the present disclosure, the first insulating film 42 and the second insulating film 44 may contain SiO₂ or SiN, and FIG. 7 shows an example in which the first insulating film 42 is formed and the second insulating film 44 is formed on the first insulating film 42, however, only one insulating film may be formed.

The hole 46 is provided to form the metal layer 60. The metal layer 60 may be, for example, a hole-type metal layer, but is not limited thereto. The hole 46 may have, for example, a circular shape, and when it has a circular shape, a diameter thereof may be greater than a width of the contact plug 20 and a width of the gate electrode 30. However, when the contact plug 20 is exposed through the corresponding hole 46, the size of the hole 46 may be determined so that the adjacent gate electrodes 30 on both sides are not exposed, and when the gate electrode 30 is at least partially exposed through the corresponding hole 46, the size of the hole 46 may be determined so that the adjacent contact plugs 20 on both sides are not exposed.

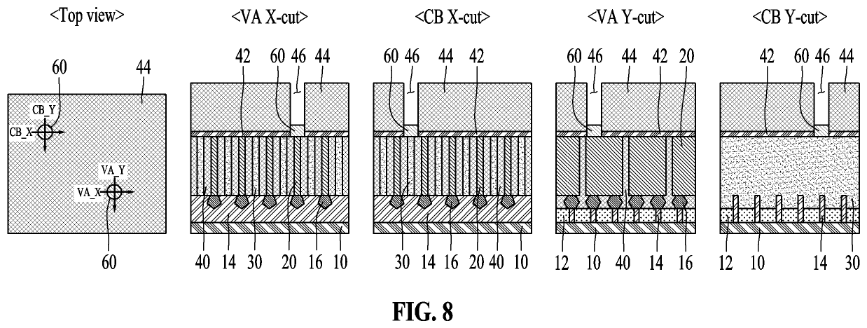

As shown in FIG. 8, according to an embodiment, a metal layer may be formed in the hole 46 where the contact plug 20 and the gate electrode 30 are at least partially exposed. The metal layer 60 formed in the hole 46 where the contact plug 20 is at least partially exposed may be used to electrically connect the metal wire 70 to the source/drain contact area CA 22 through the upper contact area VA 24. The metal layer 60 formed in the hole 46 where the gate electrode 30 is at least partially exposed may be used to electrically connect the metal wire 70 to the gate extension portion MG 32 through the gate contact CB 34.

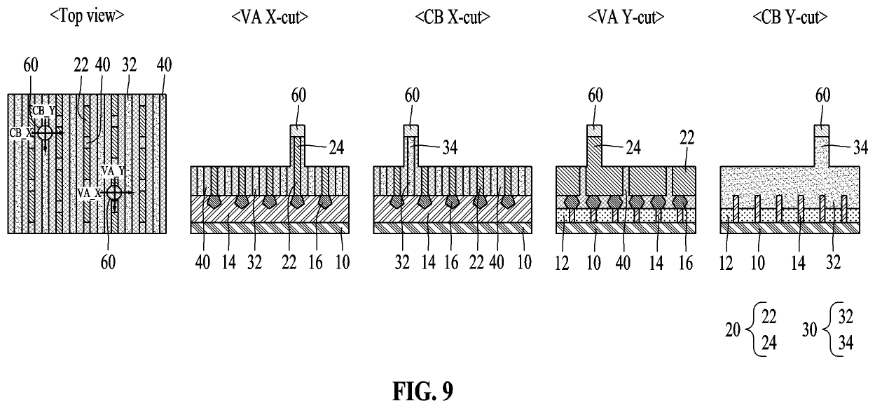

As shown in FIG. 9, according to an embodiment, the first insulating film 42, the second insulating film 44, a portion of the contact plug 20, a portion of the gate electrode 30, and a portion of the interlayer insulating layer 40, of an area other than an area where the metal layer 60 is formed, is removed.

In the operation of removing the first insulating film 42, the second insulating film 44, a portion of the contact plug 20, a portion of the gate electrode 30, and a portion of the interlayer insulating layer 40, of the area other than the area where the metal layer 60 is formed, the upper contact area VA 24, the source/drain contact area CA 22, the gate contact CB 34, and the gate extension portion MG 32 may be formed.

In the above operation, a portion of the contact plug 20 below the metal layer 60 (Z direction) may remain to form the upper contact area VA 24. Depending on the size of the hole 46, the interlayer insulating layer 40 may be provided between the upper contact area VA 24 and the insulating layer 50, and the interlayer insulating layer 40 may not be provided between the upper contact area VA 24 and the insulating layer 50.

In the above operation, a portion of the gate electrode 30 below the metal layer 60 (Z direction) may remain to form the gate contact CB 34. Depending on the size of the hole 46, the interlayer insulating layer 40 may be provided between the gate contact CB 34 and the insulating layer 50, and the interlayer insulating layer 40 may not be provided between the gate contact CB 34 and the insulating layer 50.

Because there is no interface between the source/drain contact area CA 22 and the upper contact area VA 24, the interface resistance may be reduced or eliminated, and because there is no interface between the gate extension portion MG 32 and the gate contact CB 34, the interface resistance may be reduced or eliminated.

As shown in FIG. 9, the upper surfaces of the source/drain contact area CA 22 and the gate extension portion MG 32 may be at substantially the same level (height) (Z direction). The source/drain contact area CA 22 and the gate extension portion MG 32 may be formed by etching in the same operation and may be at substantially the same level (height) (Z direction).

The upper surfaces of the upper contact area VA 24 and the gate contact CB 34 may be at substantially the same level (height) (Z direction). The upper surfaces of the upper contact area VA 24 and the gate contact CB 34 may be formed by etching in the same operation as shown in FIG. 6, and may be at substantially the same level (height) (Z direction).

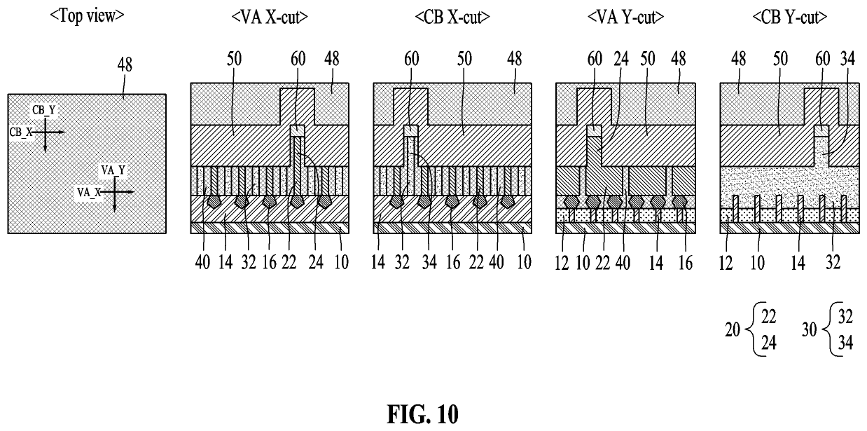

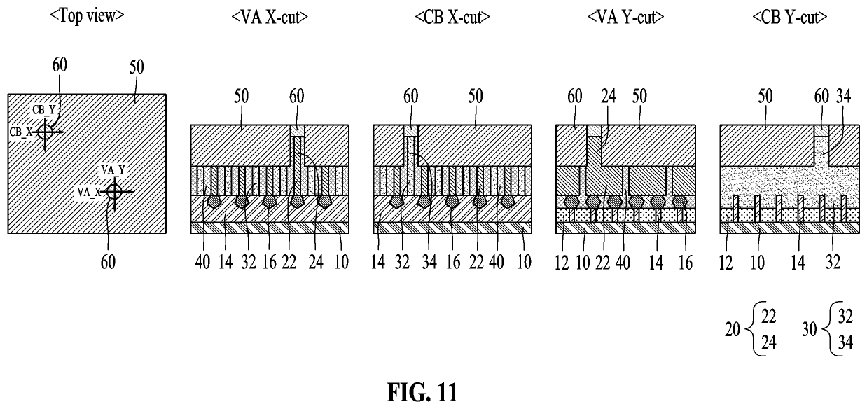

As shown in FIG. 10, according to an embodiment, the insulating layer 50 may be formed on the area, from which the first insulating film 42, the second insulating film 44, a portion of the contact plug 20, a portion of the gate electrode 30, and a portion of the interlayer insulating layer 40 are removed, and the metal layer 60, and a third insulating film 48 may be formed on the insulating layer 50. As shown in FIG. 11, according to an embodiment, a conceptual diagram of an operation of at least partially exposing the metal layer 60 by removing the third insulating film 48 and a portion of the insulating layer 50 is shown. The exposed metal layer 60 may be used to electrically connect the metal wire 70 to the upper contact area VA 24 and the gate contact CB 34.

According to another embodiment of the present disclosure, the method may further include an operation of performing NH₃ surface treatment on a surface, after the operation of exposing the metal layer 60. The NH₃ surface treatment may be NH₃ plasma treatment, and embodiments of the present disclosure are not limited thereto, and through the NH₃ surface treatment on the surface of the insulating layer 50, nitrogen atoms may be additionally introduced to increase the adhesive strength to the metal wire 70.

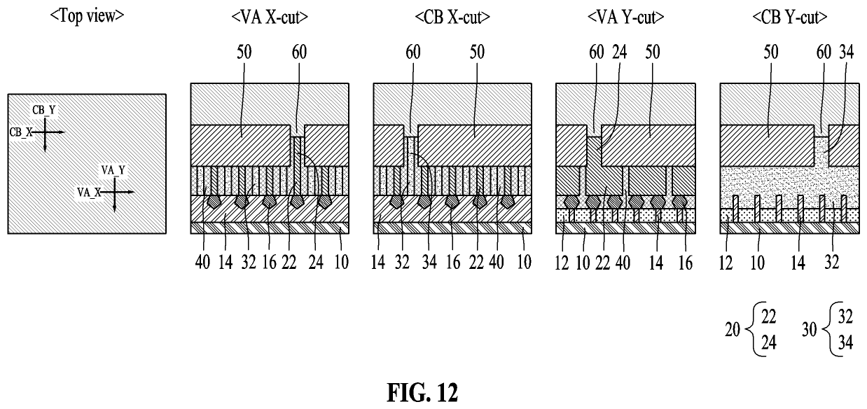

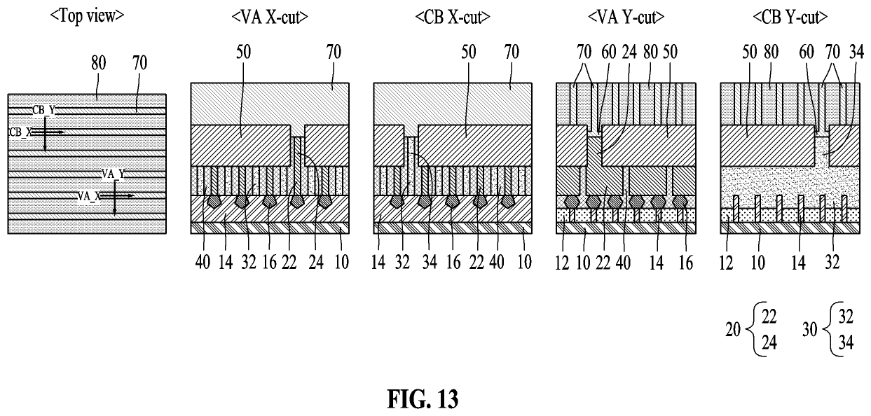

As shown in FIGS. 12 and 13, according to an embodiment, the metal wire 70 may be formed on the surface including the exposed metal layer 60. In an example, the metal wire 70 may include at least one material selected from a group consisting of Ru, W, Mo, Ni, Al, and Co, and the operation of forming the metal wire 70 may be a TiN deposition-free process. In an example, when the metal wire 70 contains Ru and the insulating layer 50 contains SiN, the adhesive strength between Ru and SiN is high, and the metal wire 70 may secure the adhesive strength to the upper contact area VA 24 and the gate contact CB 34 through the metal layer 60. Therefore, a separate adhesive layer for increasing the adhesive strength, for example, a TiN adhesive layer may not be provided. In other words, the above operation may be a TiN deposition-free process.

As described above, although the embodiments have been described, a person skilled in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents of the claims are within the scope of the following claims.

What is claimed is:

1. A semiconductor device comprising:
a substrate;
an active pattern extending in a first direction on the substrate;
a gate electrode extending in a second direction that intersects with the first direction on the substrate;
a source/drain pattern on the active pattern;
a contact plug spaced apart from the gate electrode in the first direction;
an insulating layer on the gate electrode and the contact plug;
a first metal layer on the gate electrode in a first hole extending through the insulating layer in a third direction that intersects with the first direction and the second direction;
a second metal layer on the contact plug in a second hole extending through the insulating layer in the third direction;
a first metal wire on the first metal layer and the insulating layer; and
a second metal wire on the second metal layer and the insulating layer,
wherein the gate electrode comprises a gate extension portion that intersects with the active pattern, and a gate contact protruding from the gate extension portion in the third direction and formed in the first hole, and
wherein the contact plug comprises a source/drain contact area on the source/drain pattern, and an upper contact area protruding from the source/drain contact area in the third direction and formed in the second hole.

2. The semiconductor device of claim 1, wherein
an upper surface of the source/drain contact area and an upper surface of the gate extension portion are formed at substantially a same level in the third direction, and
an upper surface of the upper contact area and an upper surface of the gate contact are formed at substantially a same level in the third direction.

3. The semiconductor device of claim 1, wherein
the first metal layer is on the gate contact and a width of the gate contact in the first direction is less than a width of the first metal layer, and
the second metal layer is on the upper contact area and a width of the upper contact area in the first direction is less than the width of the first metal layer.

4. The semiconductor device of claim 1, further comprising:
a gate spacer on a side surface of the gate electrode in the first direction; and
an interlayer insulating layer that extends between the gate spacer and the insulating layer.

5. The semiconductor device of claim 1, further comprising:
a gate spacer on a side surface of the gate contact in the first direction,
wherein the gate spacer contacts the insulating layer in the first direction.

6. The semiconductor device of claim 5, wherein the gate spacer contacts the insulating layer in the second direction.

7. The semiconductor device of claim 1, wherein the first metal layer and the first metal wire are integrally formed in a first monolithic structure, and the second metal layer and the second metal wire are integrally formed in a second monolithic structure.

8. The semiconductor device of claim 1, wherein the first metal layer, the second metal layer, the first metal wire, and the second metal wire comprise the same material.

9. The semiconductor device of claim 1, wherein the insulating layer comprises SiN, SiO₂, or a combination thereof.

10. The semiconductor device of claim 1, wherein each of the source/drain contact area, the upper contact area, the first metal layer, the second metal layer, the first metal wire, and the second metal wire comprises at least one material selected from a group consisting of Ru, W, Mo, Ni, Al, and Co.

11. The semiconductor device of claim 1, wherein each of the gate extension portion and the gate contact comprises at least one material selected from a group consisting of TiN, TiAlC, TaN, and TaAlC.

12. The semiconductor device of claim 1, wherein the source/drain contact area and the upper contact area comprise a same material, and the gate extension portion and the gate contact comprise a same material.

13. The semiconductor device of claim 1, wherein
the gate contact contacts the first metal layer, and the upper contact area contacts the second metal layer, and
the first metal wire and the second metal wire contact the insulating layer.

14. The semiconductor device of claim 1, wherein an angle between an upper surface of the first metal layer and a side surface of the first metal wire is 90° to 100°.

15. The semiconductor device of claim 1, wherein an upper surface of the first metal layer and an upper surface of the second metal layer are at substantially a same level in the third direction.

16. A method of manufacturing a semiconductor device, the method comprising:
preparing a substrate comprising a contact plug, a gate electrode, and an interlayer insulating layer;
forming a first insulating film on the contact plug, the gate electrode, and the interlayer insulating layer, and forming a second insulating film on the first insulating film, wherein the first insulating film and the second insulating film have a hole in which each of the contact plug and the gate electrode is at least partially exposed;
forming a metal layer in the hole in which the contact plug and the gate electrode are exposed;
removing the first insulating film, the second insulating film, a portion of the contact plug, a portion of the gate electrode, and a portion of the interlayer insulating layer, of an area other than an area where the metal layer is formed;
forming an insulating layer on the area, from which the first insulating film, the second insulating film, a portion of the contact plug, a portion of the gate electrode, and a portion of the interlayer insulating layer are removed, and the metal layer;
forming a third insulating film on the insulating layer;
at least partially exposing the metal layer by removing the third insulating film and a portion of the insulating layer; and
forming a metal wire on a surface comprising the exposed metal layer.

17. The method of claim 16, wherein, in the removing of the first insulating film, the second insulating film, the portion of the contact plug, the portion of the gate electrode, and the portion of the interlayer insulating layer, of the area other than the area where the metal layer is formed,
the contact plug comprises an upper contact area formed on a source/drain contact area, and
the gate electrode comprises a gate contact formed on a gate extension portion.

18. The method of claim 16, further comprising, after the at least partially exposing of the metal layer:
performing NH₃ surface treatment on a surface of the insulating layer.

19. The method of claim 16, wherein the first insulating film and the second insulating film comprise SiO₂ or SiN.

20. The method of claim 16, wherein
the metal wire comprises at least one material selected from a group consisting of Ru, W, Mo, Ni, Al, and Co, and
the forming of the metal wire is a TiN deposition-free process.
